(19) United States
(12) Patent Application Publication
(10) Pub. No.: US 2022/0359415 A1
(43) Pub. Date: Nov. 10, 2022

(54) SUPERCONDUCTING THROUGH SUBSTRATE VIAS

(71) Applicant: IQM Finland Oy, Espoo (FI)

(72) Inventors: Máté Jenei, Espoo (FI); Kok Wai Chan, Espoo (FI); Hasnain Ahmad, Espoo (FI); Manjunath Ramachandrappa Venkatesh, Espoo (FI); Wei Liu, Espoo (FI); Lily Yang, Espoo (FI); Tianyi Li, Espoo (FI); Jean-Luc Orgiazzi, Espoo (FI); Caspar Ockeloen-Korppi, Espoo (FI); Alessandro Landra, ESpoo (FI); Mario Palma, Espoo (FI)

(21) Appl. No.: 17/736,567

(22) Filed: May 4, 2022

(30) Foreign Application Priority Data
May 4, 2021 (FI) 20215520

(51) Int. Cl. H01L 23/532; H01L 21/3205; H01L 21/768; H01L 23/48; H01L 23/498; H01L 27/18

(52) U.S. Cl. CPC H01L 23/53285; H01L 21/32058; H01L 21/76898; H01L 23/481; H01L 23/49827; H01L 27/18

(57) ABSTRACT

Superconducting through substrate vias (STSVs) are disclosed. The STSVs provide superconducting interconnections between opposite faces of a substrate. In an example, a method of forming STSVs includes etching openings that extend from a first side of a substrate partially through the substrate towards a second side of the substrate. The method also includes depositing a seed layer over the first side of the substrate and interior surfaces of the openings in the substrate. The method further includes forming a resist or hardmask on the first side of the substrate above the seed layer, such that the resist or hardmask comprises openings aligned with the etched openings in the substrate. The etched openings in the substrate are filled with a superconducting filler material. The substrate is thinned by removing material from the second side of the substrate until the deposited seed layer is exposed on the second side of the substrate.

### PRIORITY CLAIM

This application claims priority to Finnish Patent Application No. 20215520, filed on May 4, 2021, the entire disclosure of which is incorporated by reference herein.

### TECHNICAL FIELD

The invention relates to the fabrication of high component density integrated circuit devices.

### BACKGROUND

In three-dimensional integrated circuit devices, the integrated circuit components occupy not just a single substrate side, but are distributed on both sides of a substrate and/or on the sides of multiple unified dice, e.g., in a stack. The distribution of circuit components on different layers or design faces provides more flexibility for qubit chip design and also enables higher component density.

Superconducting through silicon/substrate via (STSV) technology is a core aspect of high-qubit density quantum processing units. For STSVs, the two sides of a substrate are electrically connected by a (partially) metallized opening. Mitigating losses in STSVs is necessary to create a versatile three-dimensional-integrated qubit design, in which the STSV can be the part of a qubit, readout structure, or control lines.

Furthermore, in existing hollow STSV structures, securing a wafer during resist spinning—an essential step in the formation of quantum processing unit components on the wafer—requires additional fabrication steps because the hollow STSV structures prevent the formation of a sufficiently strong vacuum to hold the wafer on the spinning chuck. These additional fabrication steps may also introduce impurities that can negatively affect the performance of the superconducting connection.

### SUMMARY

According to a first aspect of the invention, a method for forming superconducting through substrate vias in a substrate is provided. The method comprises:
etching one or more openings in the substrate, the etched openings extending from a first side of the substrate partially through the substrate towards a second side of the substrate;
depositing a seed layer over the first side of the substrate and interior surfaces of the one or more etched openings in the substrate;
forming a resist or hardmask on the first side of the substrate above the seed layer, such that the resist or hardmask comprises one or more openings that are aligned with the etched openings in the substrate;
filling the etched openings in the substrate with a superconducting filler material by electroplating; and
thinning the substrate by removing material from the second side of the substrate until the deposited seed layer is exposed on the second side of the substrate.

The electroplating may be DC or pulse electroplating.

Filling the etched opening with the superconducting filler material is performed by electrodeless electroplating. Lanthanum superconducting filler material may be deposited by this process.

Filling the etched opening with superconducting filler material may be performed using an anode formed of the superconducting filler material.

The superconducting filler material may be rhenium or indium.

Before etching the one or more openings in the substrate, the method may comprise forming a second resist or second hardmask, the second resist or second hardmask comprising one or more openings through which the substrate is exposed. The one or more openings in the substrate are etched via the one or more openings in the second resist or second hardmask.

Removing material from the second side of the substrate may be carried out by chemical mechanical polishing, dry blanket etching, physical grinding, or chemical etching.

Thinning the substrate may comprise bonding the first side of the substrate to a second substrate, performing chemical mechanical polishing of the second side of the substrate until the deposited seed layer is exposed on the second side of the substrate, and debonding the substrate from the second substrate to expose the seed layer and filler material on the first side of the substrate.

Following the thinning of the substrate, the method may comprise depositing a base metal layer on the first or second side of the substrate.

Following the deposition of the base metal layer, the method may comprise patterning the base metal layer. Patterning the base metal layer may comprise depositing a resist on the base metal layer by spin coating.

Patterning the base metal layer may comprise forming components of a quantum processing unit.

According a second aspect of the invention, a product is provided. The product comprises a substrate including one or more superconducting through-substrate vias that extend through the substrate from a first side of the substrate to a second side of the substrate. Interior walls of the through-substrate vias are coated in a seed layer and the through-substrate vias are filled with a superconducting filler material.

The superconducting filler material may be rhenium or indium, for example. Other superconducting filler materials may also be used.

The seed layer may include titanium nitride, niobium titanium nitride, copper, or gold.

The seed layer includes a superconducting material, or the seed layer may be induced to form a superconductor by the proximity of the superconducting filler material, e.g., by the Holm-Meissner effect.

The seed layer may extend over the first side of the substrate such that the superconducting material within the through-substrate vias is not covered by the seed layer on the first side of the substrate.

The seed layer may extend through the through-substrate vias to the second side of the substrate such that the superconducting material within the through-substrate vias is covered by the seed layer on the second side of the substrate.

Areas of the seed layer that cover the superconducting material may be level with a surface of the second side of the substrate.

The product may further comprise a base metal layer on the first or second side of the substrate.

The base metal layer may be patterned to form components of a quantum processing unit.

The product may further comprise one or more components of a quantum processing unit that are located on the first side of the substrate.

The product may further comprise one or more components of a quantum processing unit that are located on the second side of the substrate.

At least one of the one or more components located on the first side of the substrate may be electrically connected to at least one of the one or more components located on the second side of the substrate by at least one of the one or more superconducting through-substrate vias.

### BRIEF DESCRIPTION OF THE DRAWINGS

FIGS. 1A to 11 show intermediate results of steps of an example fabrication process of the present disclosure.

FIG. 2 is a flow chart depicting the example fabrication process.

### DETAILED DESCRIPTION

The present disclosure is directed to a method for manufacturing integrated circuit devices with through-substrate vias (TSVs), e.g., through-silicon vias, to enable an electrical connection of components formed on both sides of the substrate through the vias. The method is particularly suited to the formation of superconducting TSVs that, when cooled below the critical temperature of the superconducting TSV filler material, provide superconducting electrical connection of components, such as components of a quantum processing unit, on both sides of the substrate. Such components may be, for example, Josephson junctions or other tunnelling barrier components.

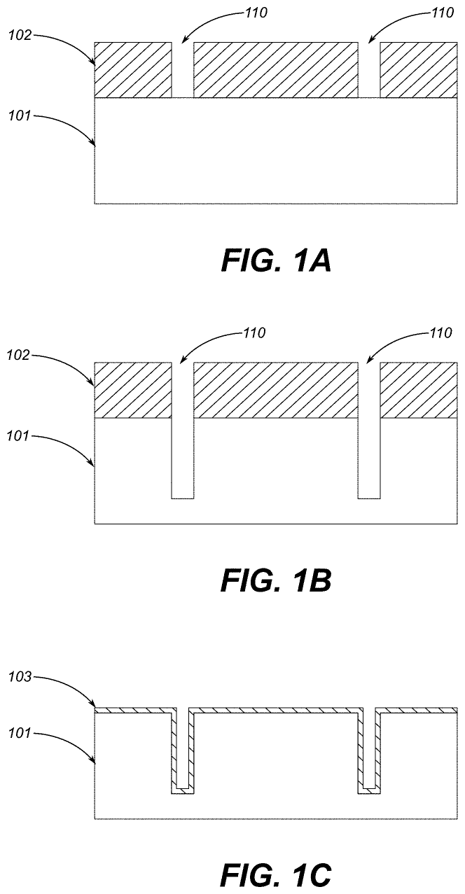

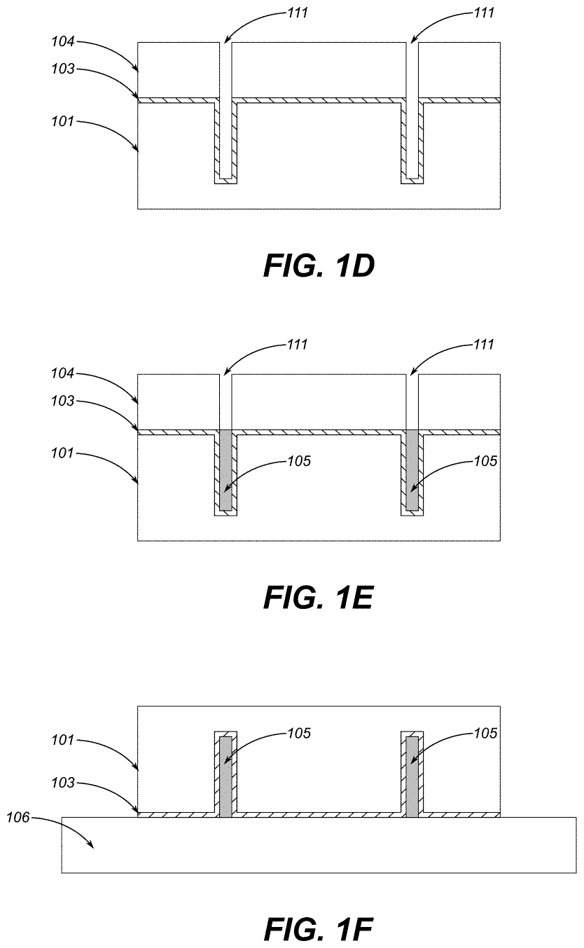

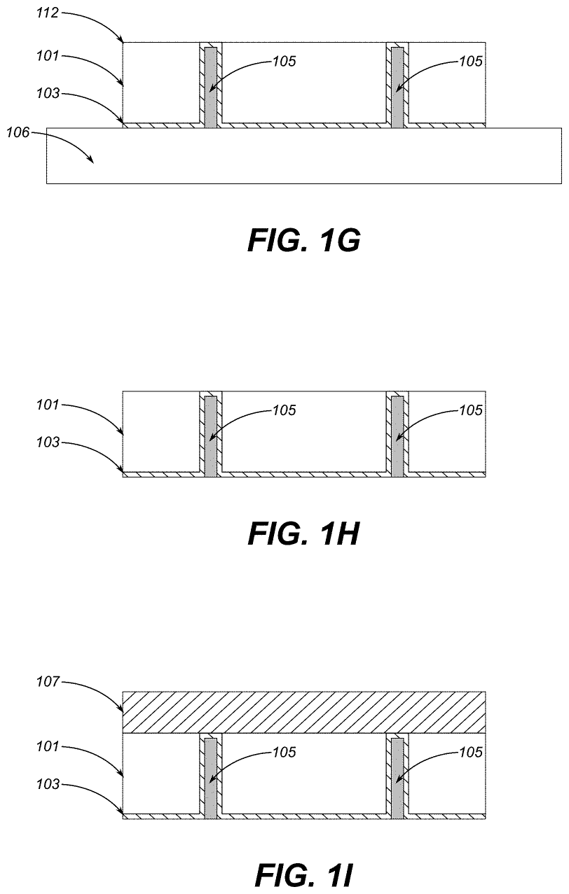

The present disclosure is also directed to an integrated circuit product that includes TSVs produced according to the present disclosure. Such products are characterised by including a substrate having one or more superconducting TSVs that extend through the substrate from a first side of the substrate to a second side of the substrate. Interior walls of the TSVs are coated in a seed layer and the TSVs are filled with a superconducting filler material. FIG. 1H shows an example of the TSVs that can be found in the product of the present disclosure.

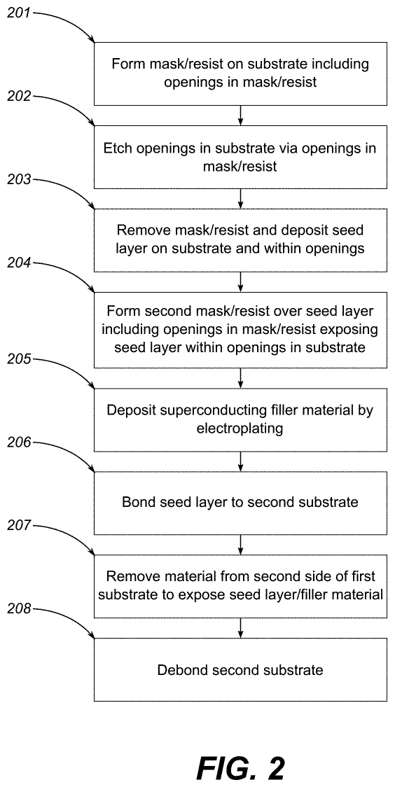

The method of the present disclosure takes place before the formation of other elements on a substrate, such as quantum circuit components like a base metal layer and Josephson junctions. The method is shown in more detail in FIGS. 1A to 11 and FIG. 2. FIGS. 1A to 11 show intermediate results of steps of an example fabrication process of the present disclosure, while FIG. 2 is a flow chart depicting the example fabrication process.

FIG. 1A shows a blank wafer or substrate 101 on which a first mask or resist 102 is formed on one side. The mask/resist 102 includes one or more openings 110, which define the locations in which the TSVs will be formed in subsequent steps. FIG. 1A shows the result of step 201 of the method shown in FIG. 2, in which the mask/resist 102 is formed on a first side of the substrate. The substrate 101 may be a silicon substrate or any other suitable substrate material, such as sapphire, III-V and IV semiconductors, or any other material that is highly resistive, can be deep etched, and tolerates a low pH electroplating bath, which is employed in later steps. The mask/resist 102 may be a hardmask or photoresist, for example, and the openings 110 may be formed by lithography or any other suitable process that enables the openings 110 to be formed in a controlled manner at specific locations above the substrate 101.

FIG. 1B shows the substrate 101 and the mask/resist 102 following deep etching of the substrate via the openings 110 at step 202 of the process shown in FIG. 2. The openings etched into the substrate 101 extend partially through the substrate in a direction that is generally perpendicular to the surfaces of the substrate 101. The etched openings are typically parallel. However, it should be appreciated that the precise direction in which the openings extend through the substrate 101 is not important as long as the openings extend from a first side of the substrate 101 towards a second side. Nor is it essential that the first and second sides of the substrate 101 are parallel. The depth of the openings in the substrate 101 defines the maximum depth of the resulting TSVs. Therefore, the openings should be etched to a depth at least equal to the minimum width of the final substrate width.

FIG. 1C shows the substrate 101 and a seed layer 103 that is deposited onto the substrate 101, including within the openings etched into the substrate 101, i.e., covering an interior wall or walls of the opening and a surface at the bottom of the opening, after the mask/resist 102 is removed. FIG. 1C therefore shows the result of step 203 of the process shown in FIG. 2. The seed layer 103 can be a single layer or a stack of multiple layers and is deposited by sputtering, e-beam evaporation, or atomic-layer deposition (ALD). The seed layer 103 is electrically conductive and forms a superconductor with the superconducting filler material. The seed layer 103 also acts as an adhesion layer, allowing a stronger bond between the substrate 101 and superconducting filler material. In an embodiment, the seed layer 103 is formed of plasma enhanced—ALD deposited titanium nitride, but other materials fulfilling the criteria set out above may be used instead, such as niobium titanium nitride. Alternatively, when physical vapor deposition is used, other materials, such as copper or gold, may be used for the seed layer 103 on the same condition that the metal stack, i.e., the seed layer and filler material, is superconducting, for example, as a result of the Holm-Meissner effect.

FIG. 1D shows the result of the following step 204 shown in FIG. 2, in which a second mask/resist 104 is deposited on the seed layer 103 above the substrate 101, i.e., such that the seed layer 103 is positioned between the mask/resist 104 and the substrate 101. Openings 111 are formed in the mask/resist 103 above the existing openings in the substrate 101 and seed layer 104, which were defined by the deep etching of the substrate 101 and subsequently coated with the seed layer 103. The second mask/resist 104 may be a hardmask or photoresist, for example, and the openings 111 may be formed by lithography or any other suitable process that enables the openings 111 to be formed in a controlled manner at specific locations above the substrate 101. The openings 111 in the mask/resist 104 cover areas of the seed layer 103 that lie above the surface of the substrate 101. For instance, edges of the mask/resist 104 may align with edges of the seed layer 103 such that only areas of the seed layer 103 that lie within the openings in the substrate 101 are exposed.

FIG. 1E shows the result after the superconducting filler material 105 is deposited within the openings in the substrate 101 by electroplating at step 205 of method shown in FIG. 2. The electroplating process is performed using the seed layer 103 as a cathode of an electrolytic cell, which also includes an anode, which may be made of an inert conductive material (“electrodeless electroplating”) or may be made from the superconducting filler material itself, and an electrolyte bath, which contains ions of the superconducting filler material that is to be deposited. The electroplating process can be driven by either direct current or by an alternating current, i.e., using pulse electroplating. For some geometries, e.g., with particularly narrow or deep openings in the substrate 101, pulse electroplating may be necessary in order to consistently fill the opening. Since the seed layer 103 is covered by the second mask/resist 104 in all areas except those within the openings in the substrate 101, the superconducting filler material 105 is deposited only within the openings.

In existing superconducting TSV processes, the TSVs are typically hollow at the end of the fabrication process as the extreme temperatures under which superconducting devices must operate cause contraction of the materials that the device is formed of at different rates. Thus, elements such as filler material within the TSVs are subject to stresses and additional pressure that may adversely affect performance of the device.

The superconducting filler material 105 is preferably rhenium. The use of rhenium is advantageous because the element has a property where its critical temperature increases under thermal contraction of the device. Furthermore, rhenium has a high melting point (3459K). Thus, rhenium does not melt and reflow under the conditions required for the fabrication of components on the substrate 101 after the TSVs have been formed. When rhenium is used, it may be electroplated in a solution of 18.2MΩ cm water, 25 mM ammonium perrhenate (VII) (99%), and 0.1M sulfuric acid (96%-98%). Water-in-salt electrolytes may also contain 5M lithium chloride (98%) and tetrabutylammonium hydrogen sulphate (98%). It should of course be appreciated that the specific rhenium bath chemistry may vary from this example.

Alternatively, other superconducting filler materials may be used, such as indium or lanthanum. Further options for the superconducting filler material include aluminium, tin, lead, niobium, or tantalum. Whether the superconducting filler material 105 is rhenium or any other superconducting material, the superconducting filler material 105 fills the opening in the substrate 101 such that the filler material 105 completely blocks the opening in the substrate 101. Therefore, other materials still retain at least the advantage that the TSVs are filled and resist spinning when forming further components after formation of the TSVs can be performed without additional fabrication steps and without contaminating the TSVs with additional materials that might cause interference or dielectric loss.

FIG. 1F shows the result of step 206 of the method of FIG. 2, in which the mask/resist 104 is removed and the seed layer 103 is bonded to a second substrate 106 to enable the removal of material from the second, exposed side of the substrate 101 using wafer thinning techniques e.g., by chemical mechanical polishing (CMP), as shown in FIGS. 1G and 1n step 207 of the method of FIG. 2. Material is removed from the second side of the substrate 101 until the seed layer 103 that was deposited at the bottom of the openings in the substrate 101 is exposed. This is sufficient to provide a superconducting connection from one side of the substrate 101 to the other, but material may continue to be removed until the superconducting filler material 105 is exposed. After the seed layer 103 or superconducting filler material 105 is exposed, the second substrate 106 is debonded at step 208 of the method shown in FIG. 2 to leave the first substrate 101 with now fully formed TSVs, as shown in FIG. 1H. It should be appreciated that other techniques than CMP can be used to expose the seed layer 103 or superconducting filler material 105 on the second side of the substrate 101, in which case the process steps shown in FIGS. 1F and 1G and steps 206, 207 and 208 may differ. Alternative techniques for exposing the seed layer 103 or superconducting filler material 105 may include physical grinding, dry blanket etching, or spin etching, for example.

In the completed TSV, the interior walls of each TSV, i.e., the interior walls of the opening in the substrate, are coated by the seed layer 103 and the TSV is filled with the superconducting filler material 105, i.e., the volume enclosed by the seed layer 103 coating the interior walls of the TSV are filled with the superconducting filler material 105.

FIG. 1I shows a further step in which a base metal layer 107 is deposited onto the substrate 101 with now formed TSVs. This is a possible first step in the fabrication of components on both sides of the substrate 101, which will ultimately be connected to one another through the TSVs. As such, FIG. 1I does not represent a step of the method of forming the TSVs per se.

It will be appreciated that, although exemplary embodiments are shown in the drawings and described above, the principles of the invention may be implemented using any number of techniques, whether those techniques are currently known or not. The scope of protection is defined by the claims and should in no way be limited to the exemplary embodiments shown in the drawings and described above.

Although specific advantages have been described above, various embodiments may include some, none, or all of the describe advantages. Other advantages may be apparent to a person skilled in the art after reviewing the description and drawings.

Modifications, additions, or omissions may be made to the apparatuses, products and methods described above and shown in the drawings without necessarily departing from the scope of the claims. The components of the products and apparatuses may be integral to one another or be provided separately. The operations of the products and apparatuses and the methods described may include more, fewer, or other steps. Additionally, the steps of the methods or the operations of the products and apparatuses may be performed in any suitable order.

1. A method for forming superconducting through substrate vias in a substrate, the method comprising:
etching one or more openings in the substrate, the etched openings extending from a first side of the substrate partially through the substrate towards a second side of the substrate;
depositing a seed layer over the first side of the substrate and interior surfaces of the one or more etched openings in the substrate;
forming a resist or hardmask on the first side of the substrate above the seed layer, such that the resist or hardmask comprises one or more openings aligned with the etched openings in the substrate;
filling the etched openings in the substrate with a superconducting filler material by electroplating; and
thinning the substrate by removing material from the second side of the substrate until the deposited seed layer is exposed on the second side of the substrate.

2. The method of claim 1, wherein the electroplating is DC or pulse electroplating.

3. The method of claim 1, wherein filling the etched opening with superconducting filler material is performed by electrodeless electroplating.

4. The method of claim 1, wherein filling the etched opening with the superconducting filler material is performed using an anode formed of the superconducting filler material.

5. The method of claim 1, wherein the superconducting filler material is rhenium or indium.

6. The method of claim 1, wherein before etching the one or more openings in the substrate, the method further comprises forming a second resist or second hardmask, the second resist or second hardmask comprising one or more openings through which the substrate is exposed, wherein the one or more openings in the substrate are etched via the one or more openings in the second resist or second hardmask.

7. The method of claim 1, wherein removing material from the second side of the substrate is carried out by chemical mechanical polishing, dry blanket etching, physical grinding, or chemical etching.

8. The method of claim 7, wherein thinning the substrate comprises:
bonding the first side of the substrate to a second substrate;
performing chemical mechanical polishing of the second side of the substrate until the deposited seed layer is exposed on the second side of the substrate; and
debonding the substrate from the second substrate to expose the seed layer and filler material on the first side of the substrate.

9. The method of claim 1, wherein following thinning the substrate, the method further comprises depositing a base metal layer on the first or second side of the substrate.

10. The method of claim 9, wherein following depositing the base metal layer, the method further comprises patterning the base metal layer, wherein patterning the base metal layer comprises depositing a resist on the base metal layer by spin coating.

11. The method of claim 9, wherein patterning the base metal layer comprises forming components of a quantum processing unit.

12. The method of claim 1, wherein the one or more openings in the resist or hardmask are aligned with the etched openings in the substrate such that edges of the resist or hardmask are aligned with edges of the seed layer and only the areas of the seed layer that lie within the openings in the substrate are exposed.

13. A product comprising a substrate, the substrate comprising one or more superconducting through-substrate vias that extend through the substrate from a first side of the substrate to a second side of the substrate, wherein interior walls of the through-substrate vias are coated in a seed layer, and wherein the through-substrate vias are filled with a superconducting filler material.

14. The product of claim 13, wherein the superconducting filler material is rhenium or indium.

15. The product of claim 13, wherein the seed layer includes titanium nitride, niobium titanium nitride, copper, or gold.

16. The product of claim 13, wherein the seed layer includes a superconducting material.

17. The product of claim 13, wherein the seed layer extends over the first side of the substrate such that the superconducting material within the through-substrate vias is not covered by the seed layer on the first side of the substrate.

18. The product of claim 13, wherein the seed layer extends through the through-substrate vias to the second side of the substrate such that the superconducting material within the through-substrate vias is covered by the seed layer on the second side of the substrate.

19. The product of claim 18, wherein areas of the seed layer that cover the superconducting material are level with a surface of the second side of the substrate.

20. The product of claim 13, wherein the product further comprises a base metal layer on the first or second side of the substrate.

21. The product of claim 20, wherein the base metal layer is patterned to form components of a quantum processing unit.

22. The product of claim 13, wherein the product further comprises one or more components of a quantum processing unit that are located on the first side of the substrate.

23. The product of claim 13, wherein the product further comprises one or more components of a quantum processing unit that are located on the second side of the substrate.

24. The product of claim 13, wherein the product further comprises:
one or more components of a quantum processing unit that are located on the first side of the substrate; and
one or more components of a quantum processing unit that are located on the second side of the substrate,
wherein at least one of the one or more components on the first side of the substrate is electrically connected to at least one of the one or more components on the second side of the substrate by at least one of the one or more superconducting through-substrate vias.

25. The product of claim 13, wherein the superconducting filler material is present only within the through-substrate vias.
